(19) United States
(12) Patent Application Publication
(10) Pub. No.: US 2018/0151591 A1
(43) Pub. Date: May 31, 2018

(54) ARRAY SUBSTRATE, MANUFACTURING METHOD THEREOF, DISPLAY PANEL AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventor: Kun LIU, Beijing (CN)

(21) Appl. No.: 15/575,421

(22) PCT Filed: Mar. 23, 2017
(86) PCT No.: PCT/CN2017/077847

§ 371 Date: Nov. 20, 2017

(30) Foreign Application Priority Data
May 12, 2016 (CN) 201610317785.4

(51) Int. Cl. H01L 27/12; H01L 23/31; H01L 21/311; H01L 21/768; H01L 21/02; H01L 23/29

(52) U.S. Cl. CPC H01L 27/124; H01L 27/1248; H01L 23/3171; H01L 27/1262; H01L 21/0274; H01L 21/76802; H01L 21/0217; H01L 27/1288; H01L 23/291; H01L 21/31111

(57) ABSTRACT

An array substrate includes a substrate base, a gate layer, and a gate insulating layer, an active layer, a source-drain electrode layer, an etching barrier layer, a planarization layer, a first electrode layer, a passivation layer and a second electrode layer sequentially formed on the substrate, wherein, a via hole is formed in the etching barrier layer, the planarization layer and the passivation layer; and the first electrode layer comprises a common electrode pattern and an anti-etching pattern; the anti-etching pattern comprises a plurality of anti-etching structures, each of the anti-etching structures is correspondingly filled into one via hole; and the second electrode layer comprises a pixel electrode pattern, the pixel electrode in the pixel electrode pattern is electrically connected to the source-drain electrode layer through the anti-etching structure in the via hole.

### CROSS-REFERENCE TO RELATED APPLICATIONS

The present application is based on International Application No. PCT/CN2017/077847, filed on Mar. 23, 2017, which is based upon and claims priority to Chinese Patent Application No. 201610317785.4, titled “ARRAY SUBSTRATE, MANUFACTURING METHOD THEREOF, DISPLAY PANEL AND DISPLAY DEVICE” filed May 12, 2016, and the entire contents thereof are incorporated herein by reference.

### TECHNICAL FIELD

The present disclosure relates to the field of display technology, and more particularly, to an array substrate, a manufacturing method thereof, a display panel and a display device.

### BACKGROUND

A Thin film transistor (TFT), as a switching device, plays an important role in the field of display technology. Producing a TFT of low-cost and high-performance has always been the goal to pursue.

A conventional TFT array product requires 8 times of masking processes. In order to save cost, generally, the process of forming the passivation layer and the process of forming the gate insulating layer of the peripheral circuit are combined into a one-step process. Then, only 7 times of masking processes are needed, shortening the production cycle. During the process of forming the passivation layer and the gate insulating layer of the peripheral circuit, it is necessary to etch the passivation layer and the gate insulating layer in the peripheral circuit region to obtain a via hole penetrating the passivation layer and the gate insulating layer. Such etching takes a long time period, and tends to laterally etch the etching barrier layer in the display region, resulting in poor lap joint between the pixel electrode and the source-drain metal layer.

It should be noted that, information disclosed in the above background portion is provided only for better understanding of the background of the present disclosure, and thus it may contain information that does not form the prior art known by those ordinary skilled in the art.

### SUMMARY

The present disclosure provides an array substrate, a manufacturing method thereof, a display panel and a display device.

In a first aspect, there is provided an array substrate, comprising: a substrate base, a gate layer, and a gate insulating layer, an active layer, a source-drain electrode layer, an etching barrier layer, a planarization layer, a first electrode layer, a passivation layer and a second electrode layer sequentially formed on the substrate, wherein, in a via hole region, a via hole is formed in the etching barrier layer, the planarization layer and the passivation layer;

the first electrode layer comprises a common electrode pattern and an anti-etching pattern; the anti-etching pattern comprises a plurality of anti-etching structures, each of the anti-etching structures is correspondingly filled into one via hole, for preventing the etching barrier layer at the via hole from being etched; and

the second electrode layer comprises a pixel electrode pattern, the pixel electrode in the pixel electrode pattern is electrically connected to the source-drain electrode layer through the anti-etching structure in the via hole.

In an embodiment, the material of the planarization layer comprises resin.

In an embodiment, the material of the first electrode layer and the second electrode layer comprises ITO (indium tin oxide).

In an embodiment, the material of the passivation layer comprises silicon nitride.

In an embodiment, the material of the etching barrier layer comprises silicon nitride.

In a second aspect, there is provided a display panel comprising the above array substrate.

In a third aspect, there is provided a display device comprising the above display panel.

In a fourth aspect, there is provided a method for manufacturing an array substrate, comprising: forming a gate layer, a gate insulating layer, an active layer, a source-drain electrode layer, an etching barrier layer and a planarization layer sequentially on a substrate base; a via hole being formed in the etching barrier layer and the planarization layer in a via hole region;

forming a first electrode layer on the planarization layer; the first common electrode layer comprising a common electrode pattern and an anti-etching pattern; the anti-etching pattern comprising a plurality of anti-etching structures, each of the anti-etching structures correspondingly filled into one via hole, for preventing the etching barrier layer at the via hole from being etched;

forming a passivation material on the first electrode layer; and etching the passivation material at the via hole by a patterning process to obtain a passivation layer;

forming a second electrode layer on the passivation layer, the second electrode layer comprising a pixel electrode pattern, the pixel electrode in the pixel electrode pattern being electrically connected to the source-drain electrode layer through the anti-etching structure in the via hole.

In an embodiment, forming the first electrode layer comprises: forming the first electrode layer with ITO; and/or forming the second electrode layer comprises: forming a second electrode layer with ITO.

In an embodiment, forming the planarization layer comprises: forming the planarization layer with resin.

### BRIEF DESCRIPTION OF THE DRAWINGS

The features and advantages of the present disclosure will be more clearly understood by reference to the following drawings, which are intended to be illustrative and not to be construed as any limitations on the present disclosure, in which:

FIG. 1 is a schematic cross-sectional view illustrating an array substrate in the related art;

FIG. 2 is a schematic cross-sectional view illustrating an array substrate in the related art;

FIG. 3 is a schematic diagram illustrating an array substrate according to an embodiment of the present disclosure;

FIG. 4 is a schematic diagram illustrating that a planarization layer is formed according to an embodiment of the present disclosure;

FIG. 5 is a schematic diagram illustrating a method for coating a photoresist to form a first electrode layer according to an embodiment of the present disclosure;

FIG. 6 is a schematic diagram illustrating a method for performing exposure and development to form the first electrode layer according to an embodiment of the present disclosure;

FIG. 7 is a schematic diagram illustrating that the first electrode layer is formed according to an embodiment of the present disclosure;

FIG. 8 is a schematic diagram illustrating a method for forming a passivation layer according to an embodiment of the present disclosure.

### DETAILED DESCRIPTION

In order to clearly understand the above objects, features and advantages of the present disclosure, the present disclosure will be further described in detail below with reference to the accompanying drawings and specific embodiments. It should be noted that, the embodiments of the present application and the features in the embodiments may be combined with each other without conflict.

In the following description, numerous specific details are set forth in order to provide a thorough understanding of the present disclosure. However, the present disclosure may also be implemented in other ways different from those described herein. Therefore, the scope of the present disclosure is not limited to the specific embodiments disclosed below.

The following describes in detail the process of forming a thin film transistor array product through seven times of masking processes in the related art.

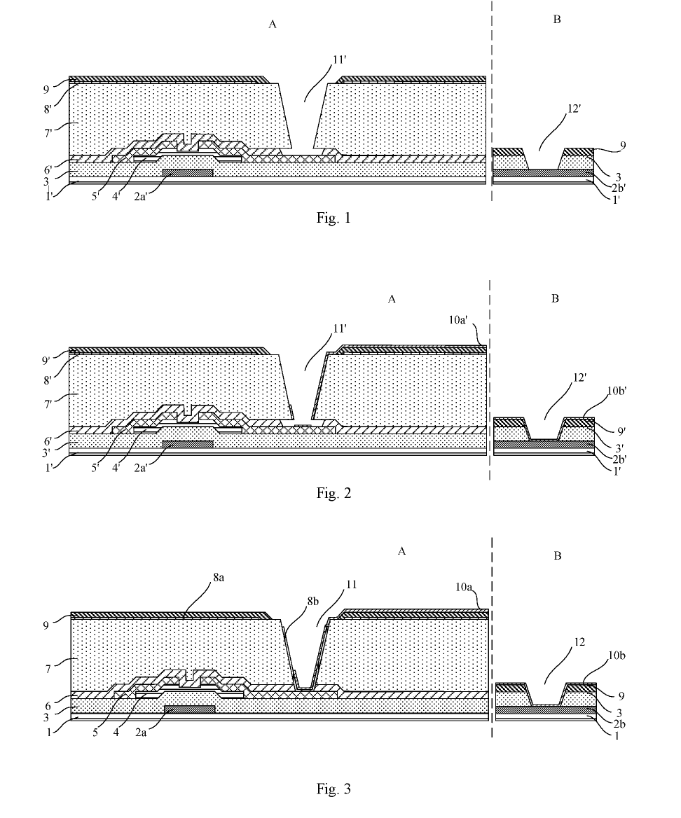

FIG. 1 illustrates an intermediate structure in an array substrate obtained by etching a passivation layer and a gate insulating layer to form a thin film transistor array product by using a masking process in the related art. The intermediate structure includes a substrate base 1′, a gate electrode 2a′ sequentially formed on the substrate base 1′, another gate layer structure 2b′ formed in the same layer with the gate electrode 2a′, a gate insulating layer 3′, an active layer 4′, a source-drain electrode layer 5′, an etching barrier layer 6′, a planarization layer 7′, a first electrode layer (common electrode layer) 8′, and a passivation layer 9′. In the display region A, a via hole 11′ has been formed in the etching barrier layer 6′, a planarization layer 7′ and the passivation layer 9′. While a via hole 12′ is being formed by etching the peripheral circuit region B, since the etching time is too long, the etching barrier layer 6′ inside the via hole region 11′ in the display region A is laterally etched, thus the problem of undercutting the planarization layer 7′ will occur, as shown in FIG. 1. Referring to FIG. 2, such a design may result in poor bonding between a pixel electrode 10a′ in the second electrode layer (including the pixel electrode 10a′ in the display region A and the structure 10b′ in the peripheral circuit region B) subsequently formed and the source-drain metal layer 5′.

In order to solve the above problem, in a first aspect, the present disclosure provides an array substrate. Referring to FIG. 3, the array substrate includes: a substrate base 1. In the display region A, the array substrate further includes a gate electrode 2a formed on the substrate base, a gate insulating layer 3 formed on the gate electrode 2a; an active layer 4 formed on the gate insulating layer 3, a source-drain electrode layers 5 formed on the active layer 4, an etching barrier layer 6 formed on the source-drain electrode layers 5, a planarization layer 7 formed on the etching barrier layer 6, a first electrode layer formed on the planarization layer 7, a passivation layer 9 formed on the first electrode layer, and a pixel electrode 10a formed on the passivation layer 9. In the via hole region, a via hole 11 is formed in the etching barrier layer 6, the planarization layer 7 and the passivation layer 9.

In the peripheral line region B, the array substrate also includes a gate layer structure 2b formed in the same layer with the gate electrode 2a, a gate insulating layer 3 formed over the gate layer structure 2b, a passivation layer 9 formed on the gate insulating layer 3 and a pixel electrode layer structure 10b which is formed on the passivation layer 9 and formed in the same layer with the pixel electrode 10a. A via hole 12 is formed in the passivation layer 9 and the gate insulating layer 3.

The first electrode layer includes a common electrode pattern and an anti-etching pattern. The common electrode pattern includes a plurality of common electrodes 8a. The anti-etching pattern includes a plurality of anti-etching structures 8b. Referring to FIG. 3, each anti-etching structure 8b is correspondingly filled into each via hole 11. The anti-etching structure 8b completely covers the etching barrier layer 6 positioned at the via hole 11, for preventing the etching barrier layer 6 at the via hole 11 from being laterally etched while the gate insulating layer of the peripheral circuit being etched for an excessively long time period. The second electrode layer 10a includes a pixel electrode pattern, and the pixel electrode in the pixel electrode pattern is electrically connected to the source-drain electrode layers 5 through the anti-etching structure in the via hole 11.

In an embodiment of the present disclosure, an anti-etching structure 8b is formed inside the via hole 11 and at the same layer with the common electrode 8a, for preventing the etching barrier layer 6 from being etched. Thus, when subsequently, the passivation layer 9 and the gate insulating layer 3 in the peripheral circuit region B are etched, the etching barrier layer 6 may be effectively protected from lateral etching, so as to ensure that the pixel electrode 10a and the source-drain electrode layer 5 formed subsequently may be well lap jointed.

In specific implementation, the material of the planarization layer 7 herein may include resin. The material of the first electrode layer and the second electrode layer 10 may include ITO or the like. The material of the passivation layer 9 may include silicon nitride. The material of the etching barrier layer 6 may include silicon nitride. The material for each layer structure mentioned above is not limited in the present disclosure as long as the corresponding functions may be implemented.

In a second aspect, an embodiment of the present disclosure further provides a method for manufacturing an array substrate, which may be used for manufacturing the above array substrate. The method may include the following steps.

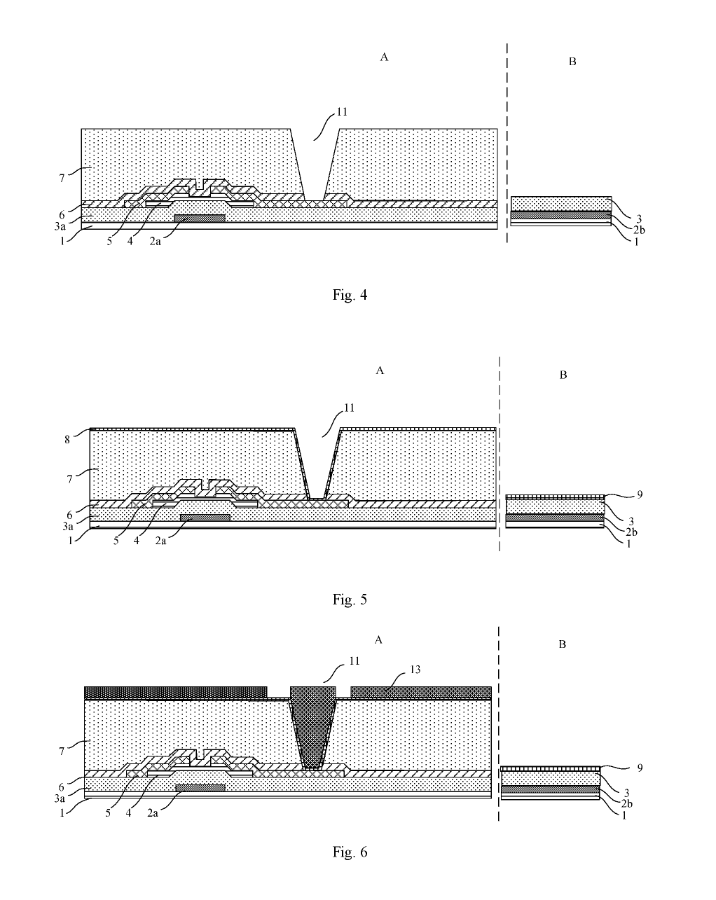

In step S1, in the display region A, a gate electrode 2a, a gate insulating layer 3, an active layer 4, a source-drain electrode layer 5, an etching barrier layer 6 and a planarization layer 7 are formed sequentially on a substrate base 1. In the via hole region, a via hole 11 is formed in the etching barrier layer 6 and the planarization layer 7. At the same time, in the peripheral circuit region B, a gate layer structure 2b is formed in the same layer as the gate electrode 2 and a gate insulating layer 3 is formed over the gate layer structure 2b. The structure obtained after the step S1 may be seen in FIG. 4.

The step of forming the gate electrode 2a, the gate layer structure 2b, the gate insulating layer 3, the active layer 4, the source-drain electrode layer 5, the etching barrier layer 6 and the planarization layer 7 on the substrate base may refer to the related art, which will not be elaborated herein.

In step S2, in the display region A, a first electrode layer material (the layer is represented as 8 for convenience of description) is formed on the structure obtained in step S1. The structure obtained after the step S2 may be seen in FIG. 5.

In step S3, a layer of photoresist is formed on the structure obtained in the step S2, and is exposed and developed to obtain a photoresist pattern 13. The photoresist pattern 13 includes a photoresist retention region and a photoresist removal region. The photoresist retention region includes a portion to be formed into an etch-resistant structure (located in the via hole 11) and a portion to be formed in a common electrode region. The structure obtained after the step S3 may be seen in FIG. 6.

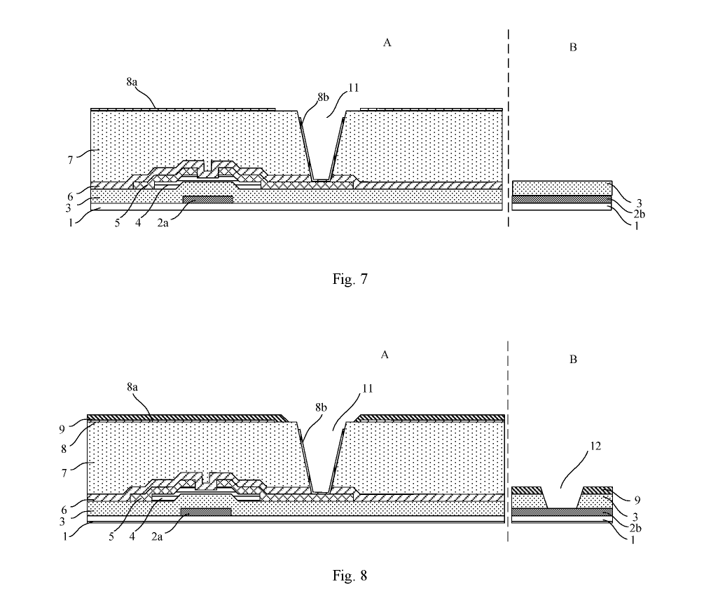

In step S4, etching is performed by using the photoresist pattern 13 formed in step S3 as a mask, to obtain a common electrode pattern and an anti-etching pattern. The common electrode pattern includes a plurality of common electrode blocks 8a. The anti-etching pattern includes a plurality of anti-etching structures 8b. Each anti-etching structure 8b is correspondingly filled into one via hole 11, for preventing the etching barrier layer 6 at the via hole 11 from being laterally etched. The structure obtained after the step S4 may be seen in FIG. 7.

Specifically, an entire layer of electrode material may be deposited on the substrate base in step S1. Since a via hole 11 is formed in the step S1, the deposited layer of electrode material may cover the planarization layer 7 in the via hole 11. By patterning the electrode material layer, a corresponding anti-etching structure may be obtained, and the common electrode pattern may be obtained.

The patterning process may specifically include: forming a photoresist on the electrode material layer, and using a mask to expose and develop the photoresist so that a corresponding photoresist pattern is obtained, and then, using the photoresist pattern as a mask, etching the electrode material layer, to obtain the anti-etching pattern and the common electrode pattern.

In step S5, a passivation layer material is formed on the structure obtained in the step S4; the substrate base formed with the passivation layer material is etched, to remove the passivation layer material in and surrounding the region of the via hole 11 inside the display region A; and the passivation layer material and the gate insulating layer material in a particular region of the peripheral circuit region B are etched to obtain a via hole 12 in the particular region. The structure obtained after the step S5 may be seen in FIG. 8.

In this step, since the gate insulating layer material in the peripheral circuit region B has to be etched, the etching may take a relatively long time. Since in the step S2, the anti-etching structure 8b which covers the gate insulating layer 3 is formed in the via hole 11, in the step S5, the etching barrier layer 6 at the via hole 11 may be effectively protected.

In step S6, a second electrode layer is formed on the structure obtained in step S5. The second electrode layer includes a pixel electrode 10a in the display region A and a second electrode layer structure 10b in the peripheral circuit region B. The structure obtained after the step S6 may be seen in FIG. 3. Since in the step S3, the etching barrier layer 6 at the via hole 11 is not etched laterally, the pixel electrode 10a may be well lap jointed with the source-drain metal layer 5.

In specific implementation, the step of forming the first electrode layer may include: forming the first electrode layer with ITO. Additionally or alternatively, the step of forming the second electrode layer may include: forming the second electrode layer with ITO. It may be understood that, the first electrode layer and the second electrode layer may be formed using other transparent conductive metal materials, which is not limited in the present disclosure.

In specific implementation, the step of forming the planarization layer includes: forming the planarization layer with resin.

In a third aspect, an embodiment of the present disclosure further provides a display panel, including the above array substrate.

In a fourth aspect, an embodiment of the present disclosure further provides a display device, which includes the above display panel.

In specific implementation, the display device herein may be any product or component having a display function such as an electronic paper, a cell phone, a tablet, a television, a display, a notebook computer, a digital photo frame and a navigator.

While the embodiments of the present disclosure have been described in conjunction with the accompanying drawings, various modifications and variations may be made by those skilled in the art without departing from the spirit and scope of the present disclosure, and such modifications and variations fall within the scope defined by the appended claims.

1. An array substrate, comprising: a substrate base, a gate layer, and a gate insulating layer, wherein an active layer, a source-drain electrode layer, an etching barrier layer, a planarization layer, a first electrode layer, a passivation layer, and a second electrode layer are sequentially formed on the substrate,
wherein, a via hole is formed in the etching barrier layer, the planarization layer, and the passivation layer;
the first electrode layer comprises a common electrode pattern and an anti-etching pattern, the anti-etching pattern comprises a plurality of anti-etching structures, and each of the anti-etching structures is correspondingly filled into one via hole; and
the second electrode layer comprises a pixel electrode pattern, and a pixel electrode in the pixel electrode pattern is electrically connected to the source-drain electrode layer through the anti-etching structure in the via hole.

2. The array substrate according to claim 1, wherein material made of the planarization layer comprises resin.

3. The array substrate according to claim 1, wherein material made of the first electrode layer and the second electrode layer comprises ITO.

4. The array substrate according to claim 1, wherein material of the passivation layer comprises silicon nitride.

5. The array substrate according to claim 1, wherein material made of the etching barrier layer comprises silicon nitride.

6. A display panel comprising the array substrate according to claim 1.

7. A display device comprising the display panel according to claim 6.

8. A method for manufacturing an array substrate, comprising:
forming a gate layer, a gate insulating layer, an active layer, a source-drain electrode layer, an etching barrier layer and a planarization layer sequentially on a substrate base; a via hole being formed in the etching barrier layer and the planarization layer;
forming a first electrode layer on the planarization layer, the first electrode layer comprising a common electrode pattern and an anti-etching pattern, the anti-etching pattern comprising a plurality of anti-etching structures, and each of the anti-etching structures correspondingly filled into one via hole;
forming a passivation material on the first electrode layer, and etching the passivation material at the via hole by a patterning process to obtain a passivation layer; and
forming a second electrode layer on the passivation layer, the second electrode layer comprising a pixel electrode pattern, the pixel electrode in the pixel electrode pattern being electrically connected to the source-drain electrode layer through the anti-etching structure in the via hole.

9. The method according to claim 8, wherein the step of forming the first electrode layer comprises: forming the first electrode layer with ITO; and
the step of forming the second electrode layer comprises: forming a second electrode layer with ITO.

10. The method according to claim 8, wherein the step of forming the planarization layer comprises: forming the planarization layer with resin.

11. The method according to claim 9, wherein the step of forming the planarization layer comprises: forming the planarization layer with resin.

12. The array substrate according to claim 2, wherein material made of the first electrode layer and the second electrode layer comprises ITO.

13. The array substrate according to claim 2, wherein material made of the passivation layer comprises silicon nitride.

14. The array substrate according to claim 3, wherein material made of the passivation layer comprises silicon nitride.

15. The display panel according to claim 6, wherein material made of the planarization layer comprises resin.

16. The display panel according to claim 6, wherein material made of the first electrode layer and the second electrode layer comprises ITO.

17. The method according to claim 8, wherein the step of forming the first electrode layer comprises: forming the first electrode layer with ITO.

18. The method according to claim 8, wherein the step of forming the second electrode layer comprises: forming a second electrode layer with ITO.
